(19) United States
(12) Patent Application Publication
(10) Pub. No.: US 2021/0333604 A1
(43) Pub. Date: Oct. 28, 2021

(54) DISPLAY PANEL AND MANUFACTURING METHOD THEREOF

(71) Applicant: WUHAN CHINA STAR OPTOELECTRONICS TECHNOLOGY CO., LTD., Wuhan, Hubei (CN)

(72) Inventor: Yantao LU, Wuhan (CN)

(73) Assignee: WUHAN CHINA STAR OPTOELECTRONICS TECHNOLOGY CO., LTD., Wuhan, Hubei (CN)

(21) Appl. No.: 16/481,098

(22) PCT Filed: Apr. 17, 2019
(86) PCT No.: PCT/CN2019/082964

§ 371 Date: Jul. 26, 2019

(30) Foreign Application Priority Data
Nov. 28, 2018 (CN) 201811436486.8

(51) Int. Cl. G02F 1/1345; H05K 1/18

(52) U.S. Cl. CPC G02F 1/13452; H05K 2201/10136; H05K 1/189

(57) ABSTRACT

A display panel and a manufacturing method of the display panel are provided. The display panel includes: a base plate, the base plate including a first region and a second region connected to each other; a substrate layer; a display region placed on the second region, the display region covering a portion of the substrate layer, the substrate layer which is not covered by the display region forming a stage region; and a circuit board. When the substrate layer is bent, one end of the substrate layer is attached onto an upper surface of the base plate, and another end of the substrate layer is attached onto a lower surface of the base plate. The manufacturing method of the display panel includes a base plate provision step, a substrate layer forming step, a display region forming step, a bonding step, a separating step, a cutting step, and a bending step.

### 1. FIELD OF DISCLOSURE

The present invention relates to a field of display devices and in particular, to a display panel and a manufacturing method thereof.

### 2. DESCRIPTION OF RELATED ART

Due to an increasing screen ratio of display panels nowadays, there is an increasing demand for an even thinner bottom border of a display panel. At present, a bottom border bonding technology has two schemes: a chip on film (i.e., chip on FPC, or COF) and a chip on glass (COG). In COG; an anisotropic conductive adhesive (ACF) is used to directly encapsulate a driving integrated circuit (IC) in a liquid crystal display (LCD).

The base plate of the display panel is usually made of glass because glass has good advantages in many aspects such as chemical stability, optical characteristics, and material costs. In the case of an LCD, the base plate is more stable if a cell gap is made of glass.

Referring to FIGS. 1 and 2, a stage region is an area where a base plate 100 is beyond a display region 200. The display region includes an active area (AA area). The stage region includes an integrated circuit 300 and a flexible circuit board 400. The stage region is made of glass, and its bending ability is not as good as a flexible substrate material, so that a screen ratio of the display panel cannot be further improved.

Referring to FIGS. 3 and 4, the stage region is an area where the base plate 100 is beyond the display region 200. The display region includes an active area (AA area). A chip on film (i.e., chip on FPC or COF) 500 is disposed within the stage region. The COF 500 is an integrated circuit disposed on a flexible printed circuit board. The stage region is made of glass and its bending ability is not as good as a flexible substrate material, so that a screen ratio of the display panel cannot be further improved.

### SUMMARY

It is an objective of the present invention to solve existing technical problems in prior art. The existing problems are that bending ability of the stage region is poor, and a screen ratio cannot be improved.

Accordingly, the present invention provides a display panel, comprising:

a base plate, the base plate comprising a first region and a second region connected to each other;

a substrate layer disposed on an upper surface of the first region;

a display region disposed on an upper surface of the second region, the display region covering a portion of the substrate layer, wherein the substrate layer, except the portion covered by the display region, forms a stage region; and

a circuit board disposed on one side of the substrate layer away from the base plate;

wherein when a middle portion of the substrate layer is bent, one end of the substrate layer is attached onto an upper surface of the base plate, and another end of the substrate layer is attached onto a lower surface of the base plate.

Moreover, the circuit board comprises an integrated circuit (IC) and a flexible printed circuit board (FPC).

Furthermore, the circuit board comprises a chip on film (COF).

Accordingly, the present invention provides a manufacturing method of a display panel, comprising steps as follows:

S1: a base plate provision step, in which a base plate is provided, and the base plate comprises a first region and a second region connected to each other;

S2: a substrate layer forming step, in which a substrate material is used to coat an upper surface of the first region to form the substrate layer;

S3: a display region forming step, in which the display region is formed on an upper surface of the second region, the display region covers a portion of the substrate layer, and a portion of the substrate layer, except the portion covered by the display region, forms a stage region;

S4: a bonding step, in which a circuit board is bonded onto an upper surface of the substrate layer in the stage region;

S5: a separating step, in which the substrate layer in the stage region is separated from the base plate;

S6: a cutting step, in which the base plate under the stage region is cut away; and

S7: a bending step, in which the substrate layer in the stage region is bent to have one end of the substrate layer attached onto a lower surface of the base plate.

Moreover, the circuit board comprises an integrated circuit (IC) and a flexible printed circuit board (FPC).

Furthermore, the circuit board comprises a chip on film (COF).

Moreover, the display region forming step comprises an array substrate preparing step, a color filter substrate preparing step, an alignment film preparing step, and a cell forming step.

Furthermore, the display region is made of a color filter.

Moreover, material of the substrate layer comprises one of materials for forming a flexible light emitting diode (LED) substrate, a polymer substrate, a metal foil substrate, and an ultra-thin glass substrate.

Moreover, the base plate is made of glass.

Advantages of the present invention: By bending a flexible substrate material to a back side of the base plate, a border of the display panel is effectively narrowed down, and a screen ratio is increased.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work or paying the premise.

FIG. 1 is a top view illustrating configuration of a lower border in a conventional chip on glass (COG) bonding technology;

FIG. 2 is a cross-sectional view illustrating the lower border in the conventional chip on glass (COG) bonding technology;

FIG. 3 is a top view illustrating configuration of a lower border in a conventional chip on film (COF) bonding technology;

FIG. 4 is a cross-sectional view illustrating the lower border in the conventional chip on film (COF) bonding technology;

FIG. 5 is a top view illustrating a display panel according to a first embodiment of the present invention;

FIG. 6 is a cross-sectional view illustrating the display panel according to the first embodiment of the present invention;

FIG. 7 is a process follow diagram illustrating the display panel according to one embodiment of the present invention;

FIG. 8 is a cross-sectional view illustrating the display panel after a bonding step according to the one embodiment of the present invention;

FIG. 9 is a cross-sectional view illustrating the display panel after a cutting step according to one embodiment of the present invention;

FIG. 10 is a cross-sectional view illustrating the display panel after a bending step according to one embodiment of the present invention; and

FIG. 11 is a cross-sectional view illustrating the display panel according to a second embodiment of the present invention.

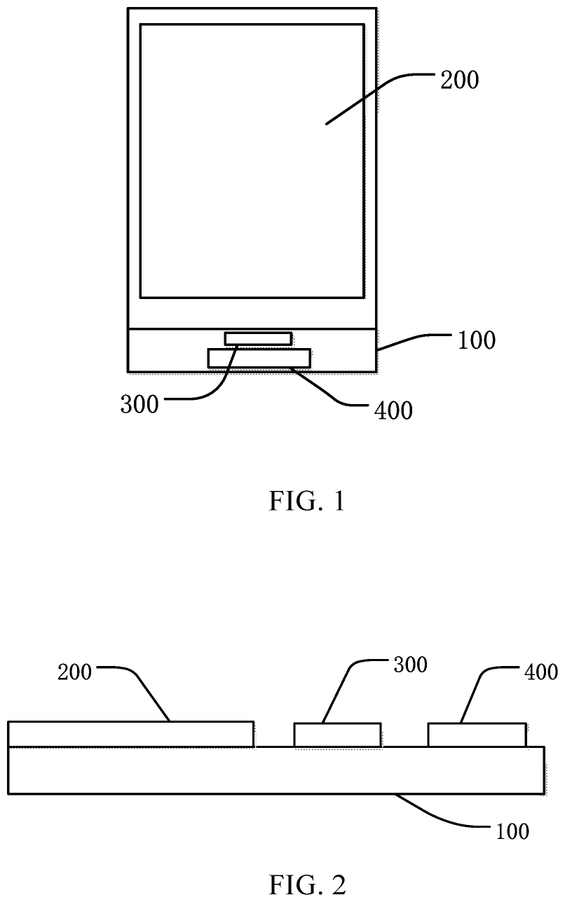

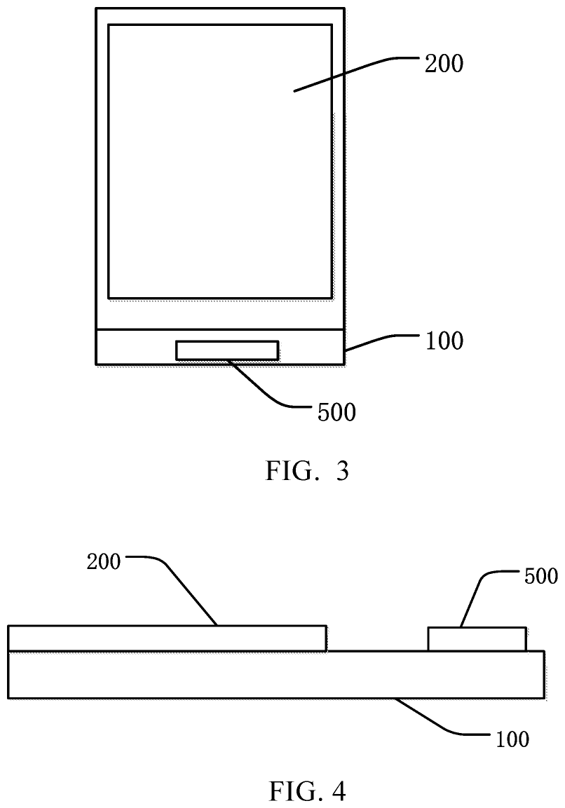

### DETAILED DESCRIPTION OF EMBODIMENTS

Preferable embodiments of the present invention are described in detail below with reference to the accompanying drawings, so that the technical content of the present disclosure will be clearer, and those skilled in the art will more readily understand how to implement the invention. The present invention may, however, be embodied in many different forms and embodiments, and the scope of the invention is not limited to the embodiments described herein. A description of the embodiments below is not intended to limit the scope of the invention.

Directional terms mentioned in the present invention, such as “upper”, “lower”, “before”, “after”, “left”, “right”, “inside”, “outside”, “side”, are intended to describe directions with reference to the drawings. The directional terms used in the present disclosure are used to explain the present invention, and are not intended to limit the scope of the present invention.

In the drawings, structurally identical components are denoted by the same reference numerals, and structurally or functionally similar components are denoted by like reference numerals. Moreover, the size and thickness of each component shown in the drawings are merely illustrative for ease of understanding, and the invention does not limit the size and thickness of each component.

When a component is described as “on” another component, the component can be placed directly on the another component; alternatively, there can also be an intermediate component on which the component is placed, and the intermediate component is placed on the another component. When a component is described as “installed to” or “connected to” another component, it can be understood as directly “mounted” or “connected”; alternatively, the component is “mounted” or “connected” to the another component through an intermediate component.

### First Embodiment

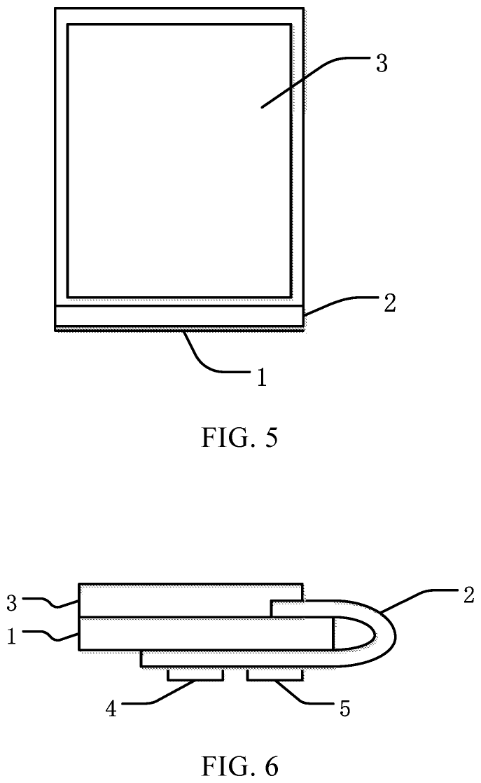

As shown in FIGS. 5 and 6, the present embodiment provides a display panel, comprising:

a base plate 1, the base plate 1 comprising a first region and a second region connected to each other;

a substrate layer 2 disposed on an upper surface of the first region of the base plate 1;

a display region 3 disposed on an upper surface of the second region of the base plate 1, the display region 3 covering a portion of the substrate layer, wherein the substrate layer 2, except the portion covered by the display region 3, forms a stage region; and

a circuit board disposed on one side of the substrate layer 2 away from the base plate 1.

According to the present embodiment, the circuit board comprises an integrated circuit (IC) 4 and a flexible printed circuit board (FPC) 5.

When a middle portion of the substrate layer 2 is bent, one end of the substrate layer 2 is attached onto an upper surface of the base plate 1, and another end of the substrate layer 2 is attached onto a lower surface of the base plate 1. The circuit board is attached to a surface of the substrate layer 2 attached to the lower surface of the base plate 1.

A length of the base plate 1 can be equal to a length of the display region 3, or can be appropriately lengthened as long as the circuit board on the substrate layer 2 can be bent to the lower surface of the base plate 1 after the substrate layer 2 is bent. The base plate 1 is made of glass.

The substrate layer 2 is made of a flexible material comprising one of materials for forming a flexible light emitting diode (LED) substrate, a polymer substrate, a metal foil substrate, and an ultra-thin glass substrate.

The display region 3 is an active area (AA), generally referring to an area for displaying a picture. The stage region is an area where the base plate 1 is beyond the color filter. A boarder is an area from the display region 3 to an edge of the base plate 1. In general, the narrower the border is, the greater a ratio of the display area is. That is, a screen ratio is greater.

The display region 3 is made of a color filter (CF).

The substrate layer of the stage region bent to a back side of the base plate 1 must include an integrated circuit 4 and a flexible circuit board 5 which are attached to the substrate layer 2. The substrate layer stays on the upper surface of the base plate 1 is connected to the base plate 1 and the color filter, so that a circuit connection between the circuit board on the substrate layer 2 and a circuit of the base plate 1 is intact, and the display panel can operate normally.

The technical function of the present embodiment is that the substrate layer is directly bent to the back side of the base plate, thus effectively narrowing a length of the border and greatly increasing a screen ratio.

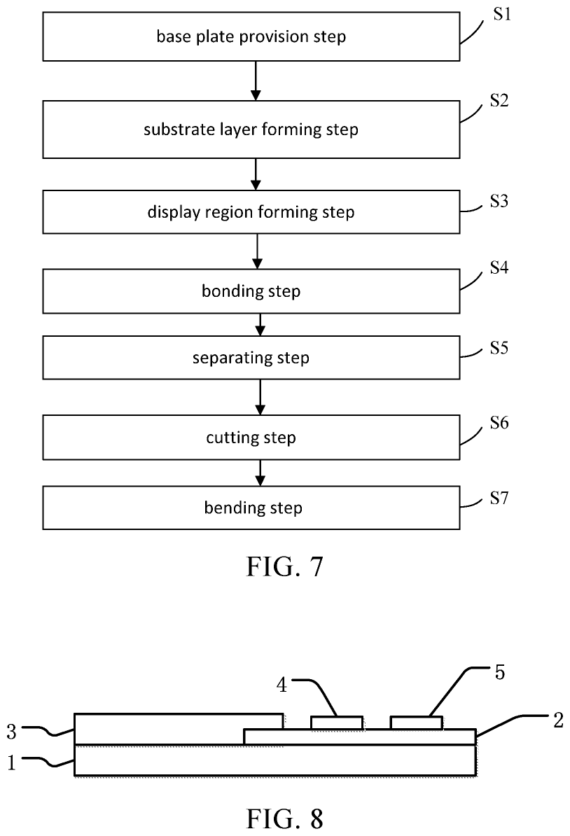

Referring to FIG. 7, the present embodiment provides a manufacturing method of a display panel, comprising steps S1 to S7 as follows:

S1: a base plate provision step, in which a base plate is provided, the base plate is made of glass, and the base plate comprises a first region and a second region connected to each other;

S2: a substrate layer forming step, in which by printing or spraying, a substrate material coats an upper surface of the first region to form the substrate layer, wherein the substrate layer is made of a flexible material which comprises one of materials for forming a flexible light emitting diode (LED) substrate, a polymer substrate, a metal foil substrate, and an ultra-thin glass substrate.

S3: a display region forming step, in which the display region is formed on an upper surface of the second region, the display region covers a portion of the substrate layer, the display region is made of a color filter, and a portion of the substrate layer, except the portion covered by the display region, forms a stage region;

S4: a bonding step, in which, circuitry of the display panel is disposed on the base plate and the substrate layer of the stage region by steps such as an array substrate preparing step and a color filter substrate preparing step, and a circuit board (it is an integrated circuit and a flexible printed circuit board in the present embodiment) is bonded onto the substrate layer in the stage region (see FIG. 8) by performing an alignment film preparing step, a cell forming step, cutting, and so forth.

S5: a separating step, in which all or part of the substrate layer having the circuit board bonded thereon is separated from the substrate, but it is required to ensure that the substrate layer still has a portion connected to the upper surface of the base plate in such a manner that an electrical connection between the circuit board on the substrate layer and the circuitry on the base plate of the display panel are intact, and therefore the display panel can operate normally.

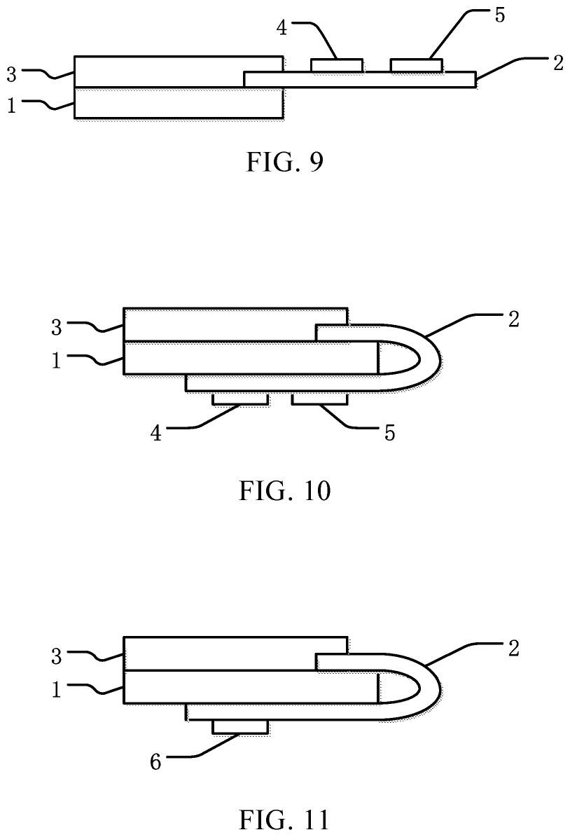

S6: a cutting step, in which all or part of the base plate of the stage region separated from the substrate layer is cut away (see FIG. 9); and

S7: a bending step, in which the substrate layer in the stage region is bent to have one end of the substrate layer attached onto a lower surface of the base plate, and it is required that the circuit board on the substrate layer be bent together to a back side of the base plate (see FIG. 10).

The technical function of the embodiment is that the substrate layer is connected to the base plate, the base plate of the stage region is cut off, and the substrate layer is directly bent, thus effectively reducing a length of the stage region, increasing a ratio of the display region, and further improving performance of the display panel.

### Second Embodiment

Referring to FIG. 11, the second embodiment is mostly the same as the technical solution in the first embodiment. The difference is that the circuit board of the second embodiment is a chip on a film (COF) 6, and the COF 6 is attached to the substrate layer and is bent to the lower surface of the base plate. The COF is an integrated circuit disposed on a flexible printed circuit board.

The display panel comprises:

a base plate 1, the base plate 1 comprising a first region and a second region connected to each other;

a substrate layer 2 disposed on an upper surface of the first region of the base plate 1;

a display region 3 disposed on an upper surface of the second region of the base plate 1, the display region 3 covering a portion of the substrate layer 2, wherein the substrate layer 2, except the portion covered by the display region 3, forms a stage region; and

a circuit board disposed on one side of the substrate layer 2 away from the base plate 1.

When a middle portion of the substrate layer 2 is bent, one end of the substrate layer 2 is attached onto an upper surface of the base plate 1, and another end of the substrate layer 2 is attached onto a lower surface of the base plate 2. The circuit board is attached to a surface of the substrate layer 2 located on a lower surface of the base plate 1.

The technical function of the embodiment is that a length of the stage region is effectively reduced, a screen ratio is increased, and the performance of the display panel is further improved.

The display panel and the manufacturing method thereof provided by the present invention are described in detail above. It should be understood that the exemplary embodiments described herein are illustrative only for ease of understanding of the main ideas and method of the present invention, and are not intended to limit the present invention. Descriptions of elements or aspects in each exemplary embodiment should generally be considered as suitable for similar elements or aspects in other exemplary embodiments. While the present invention has been described with reference to the preferred embodiments thereof, various modifications and changes can be made by those skilled in the art. Equivalent changes and modifications made in the spirit of the present invention are regarded as falling within the scope of the present invention.

What is claimed is:

1. A display panel, comprising:
a base plate, the base plate comprising a first region and a second region connected to each other;
a substrate layer disposed on an upper surface of the first region;
a display region disposed on an upper surface of the second region, the display region covering a portion of the substrate layer, wherein the substrate layer, except the portion covered by the display region, forms a stage region; and
a circuit board disposed on one side of the substrate layer away from the base plate;
wherein when a middle portion of the substrate layer is bent, one end of the substrate layer is attached onto an upper surface of the base plate, and another end of the substrate layer is attached onto a lower surface of the base plate.

2. The display panel according to claim 1, wherein the circuit board comprises an integrated circuit (IC) and a flexible printed circuit board (FPC).

3. The display panel according to claim 1, wherein the circuit board comprises a chip on film (COF).

4. A manufacturing method of a display panel, comprising steps as follows:
S1: a base plate provision step, in which a base plate is provided, and the base plate comprises a first region and a second region connected to each other;
S2: a substrate layer forming step, in which a substrate material is used to coat an upper surface of the first region to form the substrate layer;
S3: a display region forming step, in which the display region is formed on an upper surface of the second region, the display region covers a portion of the substrate layer, and a portion of the substrate layer, except the portion covered by the display region, forms a stage region;
S4: a bonding step, in which a circuit board is bonded onto an upper surface of the substrate layer in the stage region;
S5: a separating step, in which the substrate layer in the stage region is separated from the base plate;
S6: a cutting step, in which the base plate under the stage region is cut away; and
S7: a bending step, in which the substrate layer in the stage region is bent to have one end of the substrate layer attached onto a lower surface of the base plate.

5. The manufacturing method of the display panel according to claim 4, wherein the circuit board comprises an integrated circuit (IC) and a flexible printed circuit board (FPC).

6. The manufacturing method of the display panel according to claim 4, wherein the circuit board comprises a chip on film (COF).

7. The manufacturing method of the display panel according to claim 4, wherein the display region forming step comprises an array substrate preparing step, a color filter substrate preparing step, an alignment film preparing step, and a cell forming step.

8. The manufacturing method of the display panel according to claim 4, wherein the display region is made of a color filter.

9. The manufacturing method of the display panel according to claim 4, wherein material of the substrate layer comprises one of materials for forming a flexible light emitting diode (LED) substrate, a polymer substrate, a metal foil substrate, and an ultra-thin glass substrate.

10. The manufacturing method of the display panel according to claim 4, wherein the base plate is made of glass.
